(19) United States
(12) Patent Application Publication
(10) Pub. No.: US 2003/0199139 A1
(43) Pub. Date: Oct. 23, 2003

(54) Capacitor in semiconductor device having dual dielectric film structure and method for fabricating the same

(76) Inventor: Kee Jeung Lee, Seoul (KR)

Correspondence Address: LADAS & PARRY, 224 SOUTH MICHIGAN AVENUE, SUITE 1200, CHICAGO, IL, 60604, US

(21) Appl. No.: 10/330,655

(22) Filed: Dec. 27, 2002

(30) Foreign Application Priority Data
Apr. 23, 2002 (KR) 2002-22118

(51) Int. Cl. H01L 21/8242; H01L 27/108; H01L 29/76; H01L 31/119

(52) U.S. Cl. 438/240; 438/253; 438/255; 257/306; 257/309; 257/310

(57) ABSTRACT

A capacitor for a semiconductor device having a dual dielectric film structure and a fabrication method therefor. The method for fabricating the capacitor comprises the steps of: forming a lower electrode on a semiconductor substrate, forming a dielectric film of a dual dielectric film structure composed of an Al₂O₃ thin film and a Ta₂O₅ thin film on the lower electrode, and forming an upper electrode on the dielectric film. Meanwhile, the capacitor in the semiconductor device comprises: a lower electrode formed on a semiconductor substrate, a dielectric film of a dual dielectric film structure composed of a Al₂O₃ thin film and a Ta₂O₅ thin film, the dielectric film being formed on the lower electrode, and an upper electrode formed on the dielectric film.

### BACKGROUND OF THE INVENTION

1. Field of the Invention

The present invention relates to a method for fabricating a capacitor in a semiconductor device, and more particularly to a method for fabricating a capacitor in a semiconductor device having a dual dielectric film structure composed of Ta₂O₅/Al₂O₃, and a capacitor fabricated thereby.

2. Description of the Prior Art

Recently, as high integration of memory products has become accelerated following the development of microscopic fabrication process technologies for semiconductors, unit cell area has been largely decreased and driving voltages have been lowered considerably.

However, the necessary capacitance of a capacitor for the driving of memory elements is required to increase above 25 fF per cell so as to suppress the contraction of the refresh time and to prevent the occurrence of soft errors, despite the reduction of the cell area.

Accordingly, recently a three dimensional type electrical charge storage electrode with hemispheric structure having a large surface area has been used for DRAM capacitor elements which utilize a nitride layer with a nitride layer/oxide layer (N/O) structure as a dielectric, and the height of the capacitor has become increased steadily.

Meanwhile, a depth of focus is not assured in the following exposure process due to the differences of height produced between a cell region and a peripheral circuit region when the height of the capacitor increases, which results in a bad effect upon the integration process following the wiring process.

As stated above, a conventional N/O capacitor element comes to a limitation in assuring charging capacity of a capacitor requisite for future DRAM products such as those are over 256 M. As a result, as shown in FIGS. 1A to 1D, a capacitor made of Ta₂O₅ has been actively developed.

Referring to FIGS. 1A to 1D, a conventional fabricating method for a capacitor in a semiconductor device using a Ta₂O₅ dielectric film will be described as follows.

FIGS. 1A to 1D are sectional views illustrating steps in a fabricating method for a capacitor in a semiconductor device in accordance with the prior art.

According to the fabricating method of the prior art for a capacitor in a semiconductor device, as shown in FIG. 1A, an interlayer insulating film 3 is first deposited over a semiconductor substrate 1 firstly, photo-sensitive materials are distributed on the interlayer insulating film, and a first photo-mask (not shown) for making plug contacts is formed by carrying out an exposure process and a developing process using photolithography technology, and carrying out a selective patterning of the interlayer insulating film.

Then, a plug contact hole 5 exposing a portion of the semiconductor substrate 1 is formed by patterning the interlayer insulating film 3 with a first photo-mask (not shown), and the first photo-mask is removed.

Subsequently, conductive materials are deposited on the plug contact hole 5 and the first interlayer insulating film 3, and a chemical-mechanical polishing (CMP) is carried out, resulting in the formation of a contact hole 7 in the plug contact hole 5.

Referring to FIG. 1B, a second interlayer insulating film 9 is deposited on an entire surface of the semiconductor substrate 1, and then photo-sensitive materials are distributed on the second interlayer insulating film 9, and a second photo-mask (not shown) for making plug contacts is formed by carrying out an exposure process and a developing process using photolithography technology and carrying out a selective patterning of the second interlayer insulating film.

Then, a contact hole 11 defining a lower electrode region is formed in the second interlayer insulating film 9 over the contact plug 7 by patterning of the second interlayer insulating film 9 with the second photo-mask (not shown), and then the second photo-mask (not shown) is removed.

Subsequently, a doped polysilicon layer (not shown) is deposited on the second interlayer insulating film 9, inclusive of the contact hole 11, and photo-sensitive materials are distributed thereon. In this instance, the production process of the polysilicon layer (not shown) is carried out by employing a LPCVD chamber so as to use a capacitor module with a cylindrical structure or a concave structure as a lower electrode.

Then, a lower electrode 13 of cylindrical shape is formed by removing the photo-sensitive materials and the second interlayer insulating film 9 remaining after the CMP processing of the photo-sensitive materials and the doped polysilicon layer (not shown), the lower electrode being contacted with the contact plug 7. In this instance, a lower electrode having a concave structure can be formed in place of a cylindrical structure. In the above case, it is possible to remove just photo-sensitive materials to form a lower electrode in the shape of a concave structure after carrying out the CMP processing of the photo-sensitive materials and the doped polysilicon layer (not shown).

FIG. 1C shows the lower electrode 13 remaining after the removing of the photo-sensitive materials.

Referring now to FIG. 1D, a thin film 15 composed of Ta₂O₅ is deposited on the lower electrode 13 and a TiN film for an upper electrode 17 is deposited on the thin film 15, thereby fabricating a capacitor in a semiconductor device. Furthermore, a doped polysilicon layer, which functions as a buffer layer, can be deposited on the upper electrode 17 so as to secure structural stability and enhance the endurance properties of the upper electrode against thermal or electrical influences.

However, according to the above-noted prior art, vacancy atoms Ta arising from the differences of the composition ratio between Tantalum (Ta) and Oxygen (0) exist in the thin film, because the Ta₂O₅ thin film has an unstable stoichiometry.

Furthermore, carbon atoms and carbon compounds (C, CH₄, C₂H₂, etc), which are impurities, and water (H₂O) exist together in the thin film together, due to reaction of the organic compound Ta(OC₂H₅)₅ which is a precursor of Ta₂O₅, with O₂ (or N₂O) gas at the time of the formation of the thin film.

As a result, leakage current increases due to carbon atoms, ions and radicals that exist as impurities in the Ta₂O₅ thin film, and the dielectric properties become deteriorated and damaged.

As regards an Si₃N₄ (ε=7) dielectric film which is deposited by using DCS (Di-Chloro-Silane) gas, because the dielectric ratio is so low that it is limited in use as capacitor dielectric film of highly integrated semiconductor products, wherein a microscopic wiring process is employed for elements such as below 0.16 μm, therefore recently a Ta₂O₅ (ε=25) dielectric film with a bigger dielectric ratio than previously has come to be employed.

However, as stated above, although the dielectric ratio of the Ta₂O₅ thin film is big in itself, during the high temperature oxidation process which follows the deposition of Ta₂O₅ in the fabrication process of a capacitor, an interface oxide film (Si₂O, ε=3.85) having low dielectric ratio is deposited on the surface of a polysilicon layer, which functions as a lower electrode, so as to solve the problems which originate from the Ta₂O₅ thin film itself. Therefore, the thickness of the oxidation film can not be lowered to below 30 Å, resulting in limitation in achieving a large charging capacity for a capacitor.

### SUMMARY OF THE INVENTION

Accordingly, the present invention has been made to solve the above-mentioned problems occurring in the prior art, and an object of the present invention is to provide a capacitor for a semiconductor device having a dual dielectric film structure, which is capable of providing larger charging capacity for a capacitor than conventional dielectric material by employing a dual dielectric film and a fabrication method therefor.

Also, another object of the present invention is to provide a capacitor in a semiconductor device having a dual dielectric film structure, which is capable of effectively suppressing the occurrence of leakage current, thereby being suitable for highly integrated semiconductor devices, and a fabrication method therefor.

In order to accomplish the objects of the present invention, in accordance with one aspect of the present invention, there is provided a method for fabricating a capacitor in a semiconductor device with a dual dielectric film structure, the method comprising the steps of forming a lower electrode on a semiconductor substrate, forming a dielectric film of a dual dielectric film structure composed of an Al₂O₃ thin film and a Ta₂O₅ thin film on the lower electrode, and forming an upper electrode on the dielectric film.

In accordance with another aspect of the present invention, there is provided a capacitor in a semiconductor device having a dual dielectric film structure, the capacitor comprising a lower electrode formed on a semiconductor substrate, a dielectric film of a dual dielectric film structure which is composed of an Al₂O₃ thin film and a Ta₂O₅ thin film and is formed on the lower electrode, and an upper electrode formed on the dielectric film.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1D are sectional views illustrating each step in a method for fabricating a capacitor in a semiconductor device in accordance with a conventional art;

FIGS. 2A to 2D are sectional views illustrating each steps in a method for fabricating a capacitor in a semiconductor device having a dual dielectric film structure in accordance with the present invention.

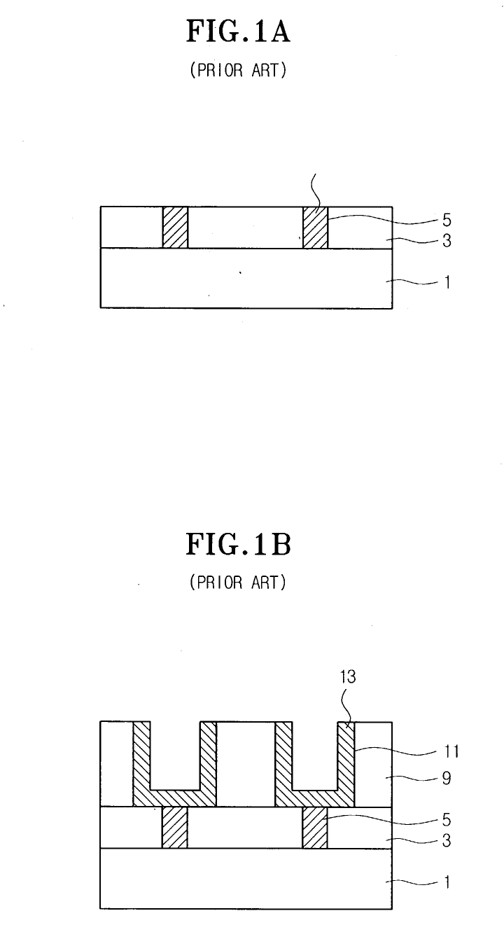

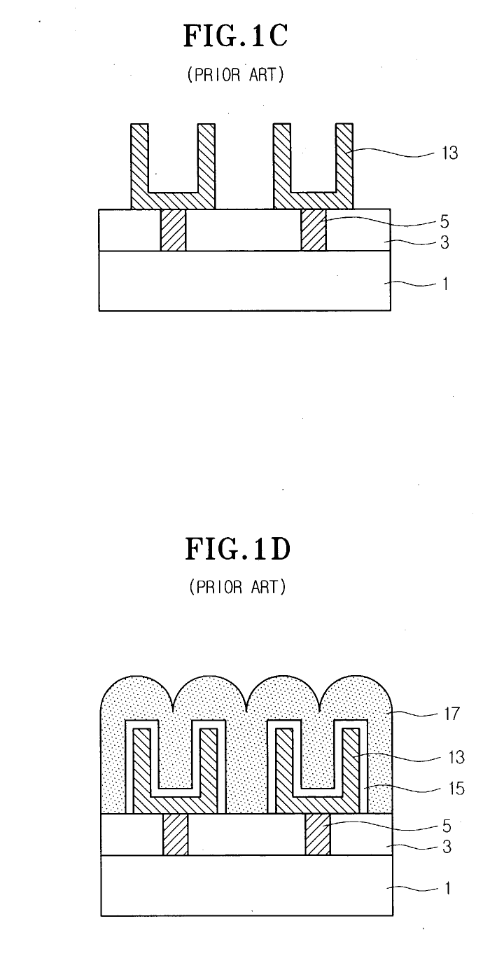

### DETAILED DESCRIPTION OF THE PREFERRED EMBODIMENTS

Hereinafter, a preferred embodiment of the present invention will be described with reference to the accompanying drawings.

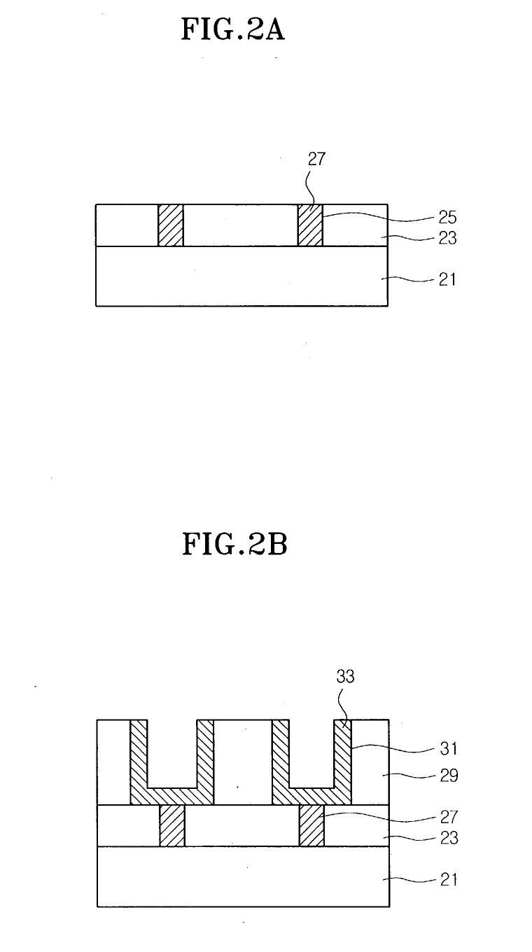

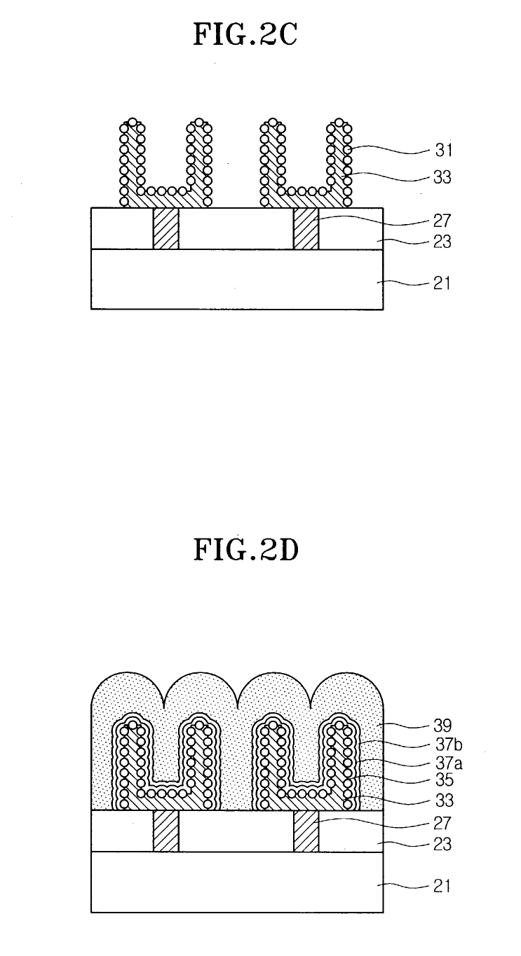

FIGS. 2A to 2D are sectional views illustrating each steps in a method for fabricating a capacitor in a semiconductor device having a dual dielectric film structure in accordance with the present invention.

In accordance with one embodiment of the present invention, as shown in FIG. 2A, a first interlayer insulating film 23 is first deposited on a semiconductor substrate 21, and then photo-sensitive materials are distributed thereon, and a first photo-mask (not shown) for making a plug contact is formed by carrying out an exposure process and a developing process using photolithography technology and selective patterning of the photo-sensitive materials.

Next, a plug contact hole 25, which exposes a portion of the semiconductor substrate 21, is formed by patterning of the first interlayer insulating film 23 using the first photo-mask (not shown) as a mask, and then the first photo-mask (not shown) is removed.

Subsequently, conductive materials are deposited over the plug contact hole 25 and the first interlayer insulating film 23, and then a CMP process is carried out to result in the formation of a contact plug 27 in the plug contact hole 25.

Referring now to FIG. 2B, a second interlayer insulating film 29 is deposited on the entire surface of the semiconductor structure and photo-sensitive materials are distributed thereon, then, a second photo-mask (not shown) is formed by carrying out an exposure process and a developing process using photolithography technology and selective patterning of the photo-sensitive materials.

Next, a contact hole 31 defining a lower electrode region is formed in the second interlayer insulating film 29 over the contact plug 27 by patterning of the second interlayer insulating film 29 with the second photo-mask (not shown) as a mask, and then the second photo-mask (not shown) is removed.

Subsequently, a doped polysilicon layer (not shown) is deposited on the second interlayer insulating film 29, inclusive of the contact hole 31, and photo-sensitive materials are distributed thereon. In this instance, the production process of the polysilicon layer (not shown) is carried out by utilizing a LPCVD chamber so as to use a capacitor module in the shape of a cylindrical structure, a stacked structure or a concave structure as a lower electrode.

Then, a lower electrode 33 of the cylindrical shape is formed by removing the photo-sensitive materials and the second interlayer insulating film 29 remaining after the CMP process of removing the photo-sensitive materials and the doped polysilicon layer (not shown), the lower electrode being contacted with the contact plug 7. In this instance, a lower electrode having a concave structure can be formed in place of that having a cylindrical structure. In the above case, it is possible to just remove photo-sensitive materials to form a lower electrode in the shape of a concave structure after carrying out the CMP process of removing the photosensitive materials and the doped polysilicon layer (not shown).

Referring now to FIG. 2C, a polysilicon layer 35 of hemi-spherical grain (HSG) shape is formed on a surface of the lower electrode 33 so as to increase the value of charging capacity for a capacitor, resulting in an increase of the area of the lower electrode 33.

Next, the surface of the polysilicon layer 35 on the lower electrode 33 is subjected to nitride treatment at a temperature of 300 to 500° C. in a plasma arrangement of an in-situ or ex-situ type, or at a temperature of 700 to 950° C. and under the atmosphere of NH₃ for 30 to 120 seconds using a RTP, so that the formation of an oxide layer with a low dielectric ratio, which is due to formation of natural oxide film (Si₂O) on the surface of the polysilicon layer in the shape of hemispherical grain shape is suppressed and the formation of an oxide film with a low dielectric ratio, which is formed during successive depositing processes of amorphous Al₂O₃ thin film, is minimized.

Alternatively, after a polysilicon layer is formed for use as a lower electrode, the natural oxide film is removed by using a HF vapor or a HF solution in an in-situ or ex-situ arrangement, and cleaning of an interface is carried out before and after carrying out surface treatment of the polysilicon layer using a HF compound, or cleaning the interface is carried out using a NH₄OH or a H₂SO₄ solution, etc., so as to enhance uniformity.

Referring to FIG. 2d, an Al₂O₃ thin film 37a is deposited on the lower electrode to a thickness of 10 to 20 Å by means of surface chemical reaction occurring on the semiconductor substrate, and a Ta₂O₅ thin film 37b is deposited on the Al₂O₃ thin film to a thickness of 50 to 100 Å by means of a CVD (Chemical Vapor Deposition) or an ALD (Atomic Layer Deposition) in a LPCVD chamber under 300 to 600° C. temperature and a pressure range of 0.1 to 5 torr. In this embodiment of the present invention, the Al₂O₃ thin film 37a is employed as a first dielectric film and the Ta₂O₅ thin film 37b is employed as a second dielectric film.

In this instance, an Al chemical vapor is employed as a source gas for the Al₂O₃ thin film 37a, and the Al chemical vapor is obtained by evaporating certain amounts of Al(OC₂H₅)₂ solution at a temperature of 150 to 300° C., which is supplied to an evaporizer or an evaporation tube by way of a flow controller such as a MFC, resulting in deposition of the Al₂O₃ thin film.

Meanwhile, an additional selective oxidizing step is carried out so as to improve the structural defects and structural homogeneity originated from a dangling bond, thereby increasing the leakage current characteristics, by means of a low temperature heat treatment of the lower electrode in an in-situ plasma arrangement under an atmosphere of NO₂ or O₂, before depositing the amorphous Al₂O₃ thin film.

In this instance, an amorphous Al₂O₃ thin film is first deposited to a thickness of 10 to 20 Å as a diffusion barrier so as to prevent an oxidant from diffusing to the lower electrode in the process of N₂O heat treatment which is performed after the deposition of the Ta₂O₅ thin film, and crystallization is induced by annealing under an atmosphere of N₂ gas at 800 to 900° C. temperature and N₂ gas for 30 to 120 seconds using an RTP.

Alternatively, an amorphous Ta₂O₅ thin film is next deposited to a desired thickness, for example, to 50 to 100 Å by means of a CVD or ALD method, after a first deposition of the Al₂O₃ thin film, and crystallization is induced by annealing under an atmosphere of N₂O (N₂ or O₂) gas at 800 to 950° C. temperature for 30 to 120 seconds using an RTP as explained above.

Meanwhile, crystallization can be induced by annealing under an atmosphere of N₂O (or O₂) gas at 700 to 800° C. temperature for 10 to 30 minutes using an electric furnace in place of an RTP.

Furthermore, the second Ta₂O₅ dielectric film 37b is deposited by means of a CVD or an ALD method using an organic metal compound such as tantalum ethylate [Ta(OC₂H₅)₅] or penta-dimethyl-amino-tantalum [Ta(N(CH₃)₂)₅] as a precursor.

In this instance, the Ta chemical vapor is obtained by the vaporization of proper amounts of tantalum ethylate [Ta(OC₂H₅)₅] solution at a temperature range of 150 to 200° C., which is supplied to an evaporizer or an evaporation tube by way of a flow controller such as a MFC (mass flow controller).

As explained above, the Ta chemical vapor, which is used for depositing the Ta₂O₅ thin film, is obtained by supplying proper amounts of an organic metal compound such as tantalum ethylate [Ta(OC₂H₅)₅] solution by way of a flow controller such as an MFC, and evaporating it at a temperature range of 150 to 200° C. in an evaporizer or an evaporation tube, and injecting it into a CVD or ALD chamber under an atmosphere of 0.1 to 5 torr by way of a supplying tube which is over 150° C. in temperature so as to suppress condensation, resulting in deposition of the Ta₂O₅ thin film.

Then, a TiN layer is deposited on the entire surface of the semiconductor device as an upper electrode 39 or is formed simultaneously with a doped polysilicon layer as a buffer layer on the upper electrode so as to secure structural stability and to enhance the endurance properties of the upper electrode against thermal or electric influences, thereby constituting a capacitor for a semiconductor device. In this instance, the upper electrode 39 is made of metallic materials such as TiN, TaN, W, WN, Ru, RuO₂, Ir, IrO₂, Pt, etc., inclusive of the doped polysilicon layer. Also, the upper electrode made of metallic material is formed through using a PE-CVD method, a RF magnetic sputtering method, a CVD method or an ALD method.

As explained above, according to the method for fabricating a capacitor in a semiconductor device having a dual dielectric film structure of the present invention, the following advantages are achieved.

According to the method of the present invention for fabricating the capacitor for a semiconductor device having a dual dielectric film structure, the capacitor in the semiconductor device is fabricated by employing dual Ta₂O₅/Al₂O₃ dielectric film as the dielectric film of the capacitor, so that the dielectric ratio thereof is bigger than that of the conventional N/O thin film (ε=4˜5) and it is substantially more capable of suppressing formation of oxide film having a low dielectric ratio itself, the oxide film being formed between interfaces with the lower electrode on which polysilicon is deposited, as has been formed in the conventional Ta₂O₅ thin film (ε=25).

Accordingly, the thickness (Tox) of the equivalent oxide film of the capacitor can be controlled to be below 20 to 30 Å, which is lower than that of the N/O capacitor (Tox=45˜55 Å) or that of the Ta₂O₅ capacitor (Tox=30˜40 Å), thereby securing a charging capacity for the capacitor larger than 25 pF per cell in highly integrated products.

In particular, a capacitor having the Al₂O₃ dielectric film of a perovskites type structure (ABO₃ structure) is more excellent in mechanical and electrical strength than a capacitor only employing the Ta₂O₅ dielectric film, and it is better in prevention of breakdowns than a capacitor having either the nitride film/oxide film (N/O) or the Ta₂O₅ dielectric film.

Thus, by employing a dual dielectric structure in a capacitor for a semiconductor device in contrast with the conventional case of only employing Ta₂O₅ thin film as a dielectric film, since the thin Al₂O₃ dielectric film, which has been crystallized already, acts as a diffusion barrier when the oxidant diffuses to penetrate into the Ta₂O₅ dielectric film during the N₂O annealing process which follows after the deposition of the Ta₂O₅ thin film, it is possible to prevent oxide film with a low dielectric ratio from being formed on the polysilicon surface in the lower electrode.

Furthermore, in the case of a capacitor having a dual Ta₂O₅/Al₂O₃ dielectric film structure, it is not only better in withstanding electrical influences from the outside, but is also higher as regards breakdown voltages than a capacitor comprising N/O or Ta₂O₅ dielectric film, and so it can provide excellent electrical characteristics with little leakage current.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method for fabricating a capacitor in a semiconductor device having a dual dielectric film structure, the method comprising the steps of:
forming a lower electrode on a semiconductor substrate;
forming a dielectric film of a dual dielectric film structure composed of an Al₂O₃ thin film and a Ta₂O₅ thin film on the lower electrode; and
forming an upper electrode on the dielectric film.

2. The method according to claim 1, wherein the lower electrode is made of a polysilicon layer and a hemispherical grain shape polysilicon layer.

3. The method according to claim 2, further comprising:
nitride treatment of a surface in a polysilicon layer by annealing in an RTP of an in-situ or an ex-situ type arrangement under an atmosphere of NH₃ for 30 to 120 seconds after forming the polysilicon layer in the lower electrode.

4. The method according to claim 2, further comprising:
removal of a natural oxide film in the polysilicon layer using a HF vapor or a HF solution in an in-situ or an ex-situ arrangement before depositing the first Al₂O₃ thin film, or cleaning an interface of the polysilicon layer using a NH₄OH or a H₂SO₄ solution before and after carrying out surface treatment of the polysilicon layer with the HF compound before depositing the first Al₂O₃ thin film.

5. The method according to claim 1, wherein the Al₂O₃ thin film is deposited to a thickness of 10 to 20 Å, and the Ta₂O₅ thin film is deposited to a thickness of 0 to 100 Å in an LPCVD chamber by means of a CVD or a ALD method under an atmosphere of 300 to 600° C. temperature and 0.1 to 4 torr pressure.

6. The method according to claim 1 or claim 5, an Al chemical vapor for the Al₂O₃ thin film is obtained by evaporating certain amounts of Al(OC₂H₅)₂ solution, having been supplied to an evaporizer or an evaporation tube by way of a flow controller such as an MFC, at a temperature of 150 to 300° C.

7. The method according to claim 1, further comprising:
selective oxidizing of the lower electrode carried out by means of a low temperature heat treatment in an in-situ plasma arrangement under an atmosphere of NO₂ or O₂, before depositing the amorphous Al₂O₃ thin film.

8. The method according to claim 1 or claim 5, further comprising:
crystallization of the amorphous Al₂O₃ thin film by annealing using an RTP under an atmosphere N₂ at 800 to 900° C. temperature for 30 to 120 minutes, after the first deposition of the amorphous Al₂O₃ thin film.

9. The method according to claim 1, further comprising:
crystallization by annealing under an atmosphere of N₂O (N₂ or O₂) gas at 800 to 950° C. temperature for 30 to 120 seconds using an RTP after depositing the first amorphous Al₂O₃ thin film and the second Ta₂O₅ thin film to a thickness of 50 to 100 Å by means of a CVD or a ALD method.

10. The method according to claim 8 or claim 9, wherein the inducing of crystallization is done by annealing under an atmosphere of N₂O (or O₂) at 700 to 800° C. temperature for 10 to 30 minutes using an electric furnace in place of an RTP.

11. The method according to claim 1, wherein the second Ta₂O₅ dielectric film is deposited by means of a CVD or an ALD method using an organic metal compound such as tantalum ethylate [Ta(OC₂H₅)₅] or penta-dimethyl-amino-tantalum [Ta(N(CH₃)₂)₅] as a precursor.

12. The method according to claim 1, wherein a Ta chemical vapor is obtained through the vaporization at a temperature range of 150 to 200° C. of proper amounts of tantalum ethylate [Ta(OC₂H₅)₅] solution, having been supplied to an evaporizer or an evaporation tube by way of a flow controller such as an MFC, resulting in deposition of the Ta₂O₅ dielectric film.

13. The method according to claim 1, wherein the second Ta₂O₅ thin film is deposited by supplying proper amounts of an organic metal compound, such as tantalum ethylate [Ta(OC₂H₅)₅] solution, by way of a flow controller such as an MFC, and evaporating it at a temperature range of 150 to 200° C. in an evaporizer or an evaporation tube in order to produce the Ta chemical vapor to be used in a CVD or an ALD method, and injecting the Ta chemical vapor into a CVD or ALD chamber under an atmosphere of 0.1 to 5 torr by way of a supplying tube which is over 150° C. in temperature so as to suppress condensation.

14. A capacitor in a semiconductor device having a dual dielectric film structure comprising:
a lower electrode formed on a semiconductor substrate;
a dielectric film of a dual dielectric film structure composed of an Al₂O₃ thin film and a Ta₂O₅ thin film, the dielectric film being formed on the lower electrode; and
an upper electrode formed on the dielectric film.

15. The capacitor in the semiconductor device according to claim 14, wherein the lower electrode is made of a polysilicon layer and a hemispherical grain shape polysilicon layer.

16. The capacitor in the semiconductor device according to claim 14, wherein the lower electrode is formed in a cylindrical structure or a concave structure.

17. The capacitor in the semiconductor device according to claim 14, wherein the upper electrode is formed in a stacked structure comprising a TiN layer and a polysilicon layer.

18. The capacitor in the semiconductor device according to claim 14, wherein the upper electrode is formed by stacking at least one metallic material selected from the group composed of TiN, TaN, W, WN, Ru, RuO₂, Ir, IrO₂, Pt, etc., inclusive of a doped polysilicon layer.
